(19) United States
(12) Patent Application Publication
(10) Pub. No.: US 2003/0180985 A1
(43) Pub. Date: Sep. 25, 2003

(54) Method for manufacturing a semiconductor device and a resin sealing device therefor

(75) Inventors: Kiyoharu Katou, Tokyo (JP); Yoshiyuki Mishima, Tokyo (JP); Itaru Matsuo, Tokyo (JP)

Correspondence Address: LEYDIG VOIT & MAYER, LTD, 700 THIRTEENTH ST. NW, SUITE 300, WASHINGTON, DC, 20005-3960, US

(73) Assignees: Mitsubishi Denki Kabushiki Kaisha, Tokyo (JP); Mitsubishi Electric Engineering Company Limited, Tokyo (JP)

(21) Appl. No.: 10/321,650

(22) Filed: Dec. 18, 2002

(30) Foreign Application Priority Data
Mar. 20, 2002 (JP) 2002-078706

(51) Int. Cl. H01L 21/44; H01L 21/48; H01L 21/50

(52) U.S. Cl. 438/106; 438/127

(57) ABSTRACT

In a resin molding method for a semiconductor device, the respective cavities of upper and lower mold blocks are faced each other when mold-clamped, and a lead frame, a semiconductor chip connected to the lead frame and a nut, overlapping and provided on a terminal portion of the lead frame, are integrally molded with a seal resin that is injected into the cavities in the mold-clamping condition, and upper and lower sides of the nut are formed to be resin-tight structures by pressure from elastic bodies.

### BACKGROUND OF THE INVENTION

1. Field of the Invention

The present invention generally relates to a manufacturing technology of a semiconductor device, in particular, to an improvement of a resin-tight structure in a molding die for sealing a resin which is used when a semiconductor device is sealed with the resin.

2. Description of the Prior Art

Conventionally, in order to mold a resin-sealed body of a semiconductor chip such as a power module provided with a resin-sealed package, a transfer molding device is generally utilized. The transfer molding device is provided with a molding die which is comprised of an upper die and a lower die to be fitted and mold-clamped with each other, having an upper cavity and a lower cavity, respectively, formed in a concave manner recessed from a confronting surface between the upper and lower dies. A gate communicated to a pot via a runner, is provided in one of the confronting surfaces of the upper and lower dies in order for injection of a liquid (i.e., melted) resin, as a molding material, into the cavities.

A lead frame is placed between the confronting surfaces of the upper and lower dies when facing each other in the mold-clamping, and a liquid resin is thereafter filled into the cavities through the runner and the gate, to thereby form a resin-sealed body of the semiconductor chip held by the lead frame. A resin-tight portion for blocking a liquid resin is formed in order to prevent generation of a resin burr due to leakage of the liquid resin between the lead frame and the confronting surfaces of the upper and lower dies facing each other when the resin-sealed body of the semiconductor chip is molded to be connected to the lead frame.

In a conventional molding die for a semiconductor device, the resin-tight portion for blocking the resin is made of metal, and therefore a molding process is carried out by applying a high surface pressure in order to prevent leakage of the liquid resin on the surfaces of a straight member such as a metal frame or a frame made of glass epoxy resin. Therefore, a very large load for a mold-clamping is necessary in the molding process and a large press is used and a great amount of energy is required. In addition, in the case where a straight member, such as a frame, is exposed on the surface of the package, it is necessary to place a member to support the load for applying a high surface pressure or to provide a frame structure having a great rigidity.

Adjustment of the surface pressure depends on a mold-clamping force of the press after venting process on the surface of the molding die. Therefore, the adjustment of the surface pressure can only be carried out by additionally processing the molding die under a constant mold-clamping force. In addition, in the case where there is dispersion in height in one straight member, unevenness of pressure on the surface is caused and, therefore, costs for the strait material and parts for the molding die increase, and the time to delivery must be lengthened in order to deal with such unevenness through a great increase in precision of the straight member and of the molding die parts.

In the case where an elastic body is adopted for the resin-tight structure, a damage is caused when the elastic body is contacted to an insert edge (edge portion for insertion) of the molding die, and the damaged portion becomes deformed or, in some cases, broken when a resin pressure is applied thereto, and therefore the life of the elastic body is shortened. In the case where an elastic body is provided in a configuration where a gap is formed so as not to allow the elastic body to make contact with the insertion edge of the molding die, the liquid resin invades this gap and becomes a burr on the product, which may cause generation of defects.

On the other hand, in the case where a sealing member is provided in the molding die, it is necessary to dismantle and reassemble the molding die chase blocks in order to exchange the sealing member. At this time, it is necessary to lower the temperature of the molding die to a room temperature and it is necessary to increase the temperature, again, through heating. Therefore, it takes a long period of time to exchange parts, including periods of time for these processes.

In the case where a resin is injected from gates in a plurality of positions of a large package, via runners, using a large tablet of a single pot, the resin is not uniformly injected so that there occur variations in length of the runners from the pot, and therefore, there may generate variation in the amount of heat received by the resin, resulting in negative effects on injection characteristics.

In addition, there is a disadvantage such that a seal resin extrudes through a portion for exposure of a heat sink (radiator plate), resulting in generation of a burr. When the exposed portion of the rear surface of the heat sink is uneven, a pressure trace on the heat sink is generated because of the load caused by the resin pressure so that unevenness of the product may, in some cases, generate. As a result, an air layer is created in an insulating layer of the rear surface of the product and, therefore, a defect in insulation may be caused in some cases.

In the configuration where lead frame terminals and nuts are integrally formed in a transfer molding die, a seal resin flows into threaded holes of the nuts in the case of a resin-tight structure made of a metal, resulting in defective products. In addition, a heavy load is required in order to obtain a sufficient surface pressure to carry out the resin-tight sealing on the metal surface. In addition, in the case where nuts are sealed by providing an elastic body on only one side of the nuts, it is necessary to use cap nuts and, therefore, a problem arises such that the costs for the strait material increase.

On the other hand, in the case where a part having a protrusion such as a terminal part, is integrally formed by transfer molding, a hole is created in the elastic body so that the protruding portion is contained. Therefore, when a distortion is given in the elastic body due to a surface pressure for resin-tight sealing, the elastic body is deformed due to insufficient rigidity, and the resin undesirably flows into the hole and resulting in a defective product, and, at the same time, a problem arises such that dismantling and cleaning are necessary due to invasion of the resin into the molding die.

### SUMMARY OF THE INVENTION

The present invention has been made to solve these problems and has an essential objective thereof is to provide a manufacturing method for a semiconductor device and a resin molding device therefor wherein a function of sealing each of exposed portions of a member having exposed portions at the time of molding is achieved under a low surface pressure so as to reduce a press load and enhance an efficiency of power utilization as well as to enhance a production efficiency.

Another objective of the present invention is to provide a manufacturing method for a semiconductor device and a resin molding device therefor wherein a resin-tight structure of an elastic body is adopted in a configuration such that a gap is created so as to prevent the elastic body from making contact with an insertion edge of a molding die, thereby preventing a resin, without fail, from entering the gap and from causing a burr, which causes generation of a defect in a product.

Another objective of the present invention is to provide a resin molding device for a semiconductor device wherein a thickness tolerance of a straight member and an assembly tolerance thereof, as well as a tolerance of a molding die can be absorbed within an amount of flexure thereof, so that it becomes possible to increase the tolerance of the straight member even in the case where there is dispersion in dimensions of a plurality of exposure portions in one straight member exposed from a package, whereby reduction in cost of the straight member and reduction in manufacturing process can be achieved.

Further another objective of the present invention is to provide a resin molding device for a resin-sealed structure of a semiconductor device wherein a melt resin can be prevented from extruding into an exposed portion of a rear surface of a heat sink, whereby a process for removal of burrs on the rear surface of the package becomes unnecessary and, thus, enhancing a production efficiency.

In addition, another objective of the present invention is to provide a resin molding device for a semiconductor device wherein unevenness does not generate in an exposed portion of a heat sink due to a resin pressure and generation of an air layer can be prevented when an insulating layer is provided over the exposed portion of the heat sink in the product, whereby defective products can be decreased in number and production efficiency can be increased.

Further another objective of the invention is to provide a resin molding device for a semiconductor device wherein a resin can be blocked from flowing into a nut hole in a configuration that a straight member, such as a nut, having a hole is integrally formed with another member by transfer molding, whereby reduction in cost of the straight member can be achieved.

In addition, another objective of the present invention is to provide a resin molding device for a semiconductor device, wherein in the case where a part having a protrusion such as a terminal part is integrally formed by transfer molding, the part can be prevented from being deformed due to a resin pressure, while rigidity of an elastic body is maintained.

Further another objective of the present invention is to provide a resin molding device for a semiconductor device wherein in a configuration such that a gap is created so as to prevent an elastic body from making contact with an insert edge of a molding die, a lifetime of the elastic body is prolonged, preventing a resin from entering such a scratch due to the contact, preventing destroy or deformation of the elastic body, and preventing the resin from entering the gap between the elastic body and the molding die with a simple sealing structure.

In addition, another objective of the present invention is to provide a resin molding device wherein not only generation of resin burrs can be reduced, but also modification of gate forms according to cavities and injection control, such as an injection speed, can be carried out, whereby the resin can be uniformly supplied to a package of a large volume to be molded such as a module, and resin injection conditions can be stable, increasing a production efficiency.

In order to achieve the above described objectives, a first aspect of the present invention is a method for manufacturing a semiconductor device through molding with a seal resin, which includes: a process of mold-clamping upper and lower mold blocks to be fitted each other by confronting upper and lower mold cavities of the upper and lower mold blocks, respectively; a process of injecting the seal resin into the upper and lower mold cavities under the mold-clamped condition; and a process of integrally sealing a lead frame, a semiconductor chip held by the lead frame and a nut disposed on a terminal portion of the lead frame to be covered with the injected seal resin under the mold-clamped condition. In this method, upper and lower sides of the nut are pressed by upper and lower elastic members, respectively, under the mold-clamped condition, to thereby provide a resin-tight structure for preventing contact with the seal resin.

By this method, both sides of the nut are provided with resin-tight structures by the elastic bodies and, therefore, effects are obtained such that, the resin can be prevented from flowing into the nut hole under a low surface pressure for resin-tight sealing and a special nut such as a cap nut is not necessary, and a semiconductor device can be provided at a low cost.

A second aspect of the present invention is a method for manufacturing a semiconductor device through molding with a seal resin, which includes: a process of mold-clamping upper and lower mold blocks to be fitted each other by confronting upper and lower mold cavities of the upper and lower mold blocks, respectively; a process of injecting the seal resin into the upper and lower mold cavities under the mold-clamped condition; and a process of integrally sealing a lead frame, a semiconductor chip held by the lead frame and a radiator plate having a quadrangular main surface on which the lead frame is fixed, to be covered with the injected seal resin under the mold-clamped condition, while a rear surface of the radiator plate is exposed from the seal resin. In this method, a pin provided in the upper mold block is abutted to at least a portion of the main surface of the radiator plate in the vicinity of the side region integrally fixed to the lead frame portion, and the rear surface of the radiator plate is abutted by pressure onto the bottom surface of the lower mold cavity, under the mold-clamped condition.

By this method, the effects are obtained such that the number of resin burrs caused on the rear surface of the radiation place can be reduced.

A third aspect of the present invention is a method for manufacturing a semiconductor device through molding with a seal resin, which includes: a process of mold-clamping upper and lower mold blocks to be fitted each other by confronting upper and lower mold cavities of the upper and lower mold blocks, respectively; a process of injecting the seal resin into the upper and lower mold cavities under the mold-clamped condition; and a process of integrally sealing a lead frame and a semiconductor chip held by the lead frame, to be covered with the injected seal resin under the mold-clamped condition. In this method, when in the mold-clamping, a stick-shaped electrode protruding upward from the semiconductor chip is entirely received by a cylinder body protruding downward from the upper mold block, and an elastic member provided at least around a tip end of the cylinder body is tightly contacted with a surface of the semiconductor chip.

By this method, the effect is obtained such that a non-seal region such as an electrode or the like part provided within the cavity can be prevented from being sealed with a seal resin in a simple configuration.

A fourth aspect of the present invention is a resin sealing device for a semiconductor device, which includes: a pair of upper and lower mold blocks to be mold-clamped each other, forming upper and lower mold cavities by the upper and lower mold blocks, respectively, to be confronted. The upper and lower mold cavities is to be filled with a seal resin under the mold-clamped condition. The resin sealing device further includes a lead frame and a semiconductor chip held by the lead frame, to be integrally sealed with the seal resin under the mold-clamped condition.

In this construction, a through-hole is formed in, at least, one of the upper mold block and the lower mold block, and an elastic member is provided within the through-hole, and the elastic member is deformed under the mold-clamped condition so that a tip end of the elastic member is tightly contacted with a non-seal surface region of the lead frame to thereby prevent the seal resin from entering the non-seal surface region of the lead frame, and that a side surface of the elastic member is tightly contacted with an inner side surface of the through-hole to thereby prevent the seal resin from leaking through the through-hole.

By this configuration, the seal resin is blocked from entering the unsealed region and also can be blocked from leaking through the through-hole having the elastic body provided therein, and an inexpensive resin sealing device of a simple structure can be provided.

### BRIEF DESCRIPTION OF THE DRAWINGS

These and other objects and features of the present invention will be readily understood from the following detailed description taken in conjunction with preferred embodiments thereof with reference to the accompanying drawings, in which like parts are designated by like reference numerals and in which:.

FIGS. 1A to 1E are cross sectional views schematically showing a resin sealing structure and a resin sealing process for a semiconductor device according to a first embodiment of the present invention;

FIGS. 2A and 2B are cross sectional views schematically showing a molding structure for a semiconductor device according to a second embodiment of the present invention;

FIGS. 3A and 3B are cross sectional views schematically showing a molding structure for a semiconductor device according to a third embodiment of the present invention;

FIGS. 4A and 4B are cross sectional views schematically showing a molding structure for a semiconductor device according to a fourth embodiment of the present invention; and

FIG. 5 is a layout diagram of a lower molding die of a resin sealing device for a semiconductor device and a product according to a fifth embodiment of the present invention.

### DETAILED DESCRIPTION OF THE PREFERRED EMBODIMENTS

Before the description proceeds, it is to be noted that, since the basic structures of the preferred embodiments are in common, like parts are designated by the same reference numerals throughout the accompanying drawings and repetition of descriptions is omitted.

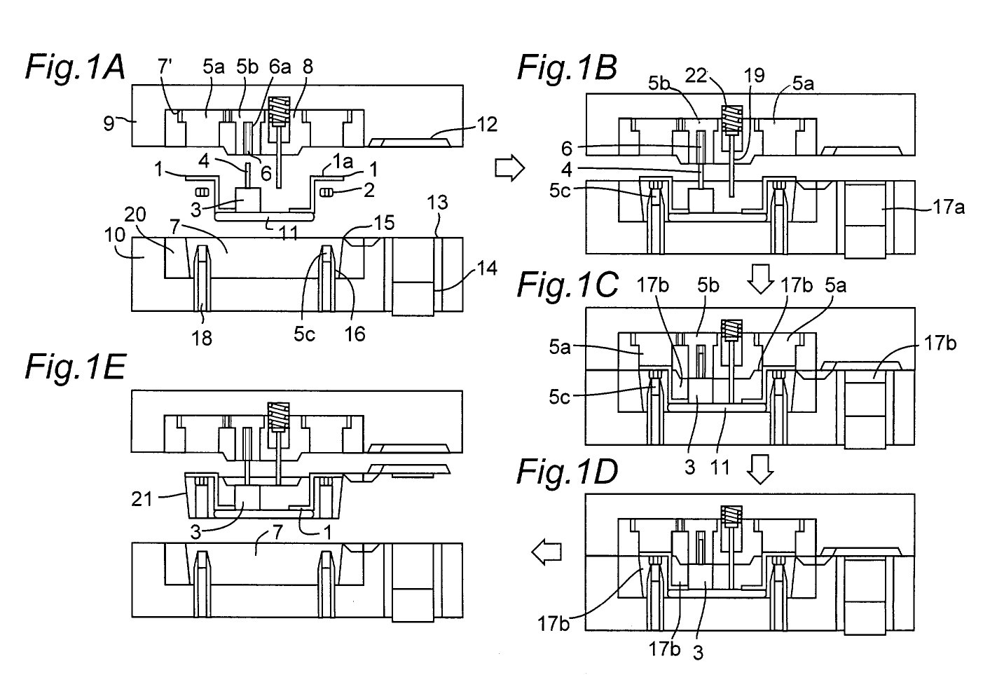

In the following, the embodiments of the present invention are described with reference to the attached FIGS. 1 to 5.

First Embodiment

FIGS. 1A to 1E are cross sectional views schematically showing a resin sealing structure and a resin sealing process for manufacturing a semiconductor device according to a first embodiment of the present invention. In these figures, reference numeral 1 denotes a lead frame, 2 denotes nuts, and 3 denotes a terminal unit such as a semiconductor device or the like chip having a terminal pin 4 protruded therefrom. Reference numerals 5a, 5b and 5c denote elastic bodies, and 6 denotes a hole for receiving the terminal pin 4.

Reference numerals 7 and 7′ denote lower and upper mold cavities, respectively, 8 denotes an upper mold cavity insert (block), 9 denotes an upper mold block as an upper retainer of an upper molding die, 10 denotes a lower mold block as a lower retainer of a lower molding die, and 20 denotes a lower mold cavity insert (block). The elastic bodies 5a and 5b are provided within the upper mold cavity insert block 8 held in the upper mold cavity 7′, while the elastic bodies 5c are disposed on upper portions of a plurality of support posts 16 provided in the lower mold cavity 7. The lead frame 1 is mechanically connected to a heat sink 11 on which the terminal unit 3 and other semiconductor devices (not shown) are mounted.

The operation thereof is described in the following. First, a plurality of nuts 2 are mounted on and contacted with the upper surface portions of the elastic bodies 5c disposed on the upper portions of the support posts 16, and the lead frame 1 connected to the heat sink 11 is installed into the lower mold cavity 7. At this time, a plurality of semiconductor devices in a pre-sealed condition, i.e., before being sealed with a resin, are mounted on the lead frame 1.

Next, an epoxy resin 17a is introduced into a chamber 13 formed within the lower retainer 10, the upper and lower molding dies are fitted together, and a force for mold-clamping is applied. At this time, the elastic body 5a provided in the upper mold cavity insert block 8 is pressed onto an upper surface portion (connection terminal portion) 1a of the lead frame 1 exposed above the nut 2, while the elastic body 5b is pressed onto an upper surface of the terminal unit 3 supporting the terminal pin 4. In this configuration, the terminal pin receiving hole 6 is formed in the elastic body 5b for allowing the terminal pin 4 to be received therein and a frame 6a is provided on the inner periphery surface of the hole 6 so as to maintain a rigidity of the elastic body 5b.

In addition, a compressive spring means 22 is secured in the upper mold cavity insert block 8 and a plurality of pressing pins 19 for pressing the heat sink 11 are attached in the lower edge portion of the compressive spring means. In the mold-clamping process, these plurality of pressing pins 19 are pressed onto the upper surface of the heat sink 11, and the rear surface of the heat sink 11 is pressed against the bottom surface of the lower mold cavity 7 due to a resilient force of the compressive spring means 22. Since the heat sink 11 is contacted with the bottom surface of the lower mold cavity 7, the bottom surface of the lower mold cavity 7 and the rear surface of the heat sink 11 are formed to have smooth surfaces so that the heat sink 11 is prevented from deforming by the pressure of the injected resin.

In the mold-clamping process, the elastic body 5a, which has made contact with and has pressed against the exposed upper surface portion 1a of the lead frame 1, becomes distorted due to the elasticity of the elastic body itself and the resilient force thereof provides a surface pressure against the exposed upper surface portion 1a of the lead frame 1 so as to have a sealing function from a melted epoxy resin 17b. Similarly, the elastic body 5b is pressed against the upper surface of the terminal unit 3 and becomes distorted due to the elasticity of the elastic body itself and the resilient force thereof provides a surface pressure against the upper surface of the terminal unit 3 so as to form a resin-tight structure having a shielding effect for blocking the melted epoxy resin 17b from entering.

At this time, the elastic bodies 5c installed on the upper portions of the support posts 16, contacting with the nuts 2, also receive the resilient force from elastic body 5a via the lead frame 1 and nuts 2 and become distorted due to the elasticity of the elastic bodies 5c themselves, so that the resilient force thereof provides a surface pressure against the rear surfaces (lower side surfaces) of the nuts 2, thereby securing a sealing function for blocking the melted epoxy resin 17b from entering.

As shown in FIGS. 1C and 1D, after the completion of the mold-clamping, the epoxy resin 17a, which has been introduced into the chamber 13, is injected into the lower mold cavity 7 through the gate 15 from a cull 12 formed in the upper retainer 9 by means of a plunger 14 for injection and, then, a pressure is applied. Though the injected melted epoxy resin 17b flows within the lower mold cavity 7, the melted epoxy resin 17b is prevented from invading the surfaces of the respective portions pressed by the elastic bodies 5a, 5b and 5c and the rear surface (lower surface) of the heat sink 11, which is pressed by means of the pressing pins 19.

During the mold-clamping process, the epoxy resin 17b, which is thermoset, is cured and, after the mold is opened, the cured epoxy resin is removed from the lower mold cavity 7 using an ejector (not shown), or the like, as shown in FIG. 1E. This becomes a semiconductor device 21 which has been sealed with the resin, and thus the resin sealing process is completed.

According to the present embodiment, an elastic body is utilized as a resin-sealing member for blocking a a melted resin and the elastic body is provided on the parting surface of a molding die, so that a member to be exposed at the time of molding is pressed by a surface pressure to allow resin sealing, thereby achieving the sealing function of the respective exposed surfaces under a low surface pressure.

In addition, only a small press load per a molded product having the same size is required and an efficiency of utilization of a power is increased so as to obtain a high production efficiency. In addition, only a small press load is required so that a production press can be reduced in size, an area occupied by equipment per a produced package can be reduced and floor utilization efficiency in a factory is improved. In addition, it is possible to form an exposed integral member to which a high surface pressure cannot be applied or utilizing a straight member having a low strength becomes possible.

Furthermore, a surface pressure for sealing is generated by using a resilient force of an elastic body when the elastic body itself is distorted and, therefore, the surface pressure for sealing applied to the elastic body can be adjusted by varying a shape of the elastic body itself. Here, in a press for generating a mold-clamping force greater than a specific level, a desired surface pressure for sealing may be obtained by changing a distortion ratio through change in the shape of the elastic body instead of changing the press load.

In addition, the distortion ratio of the elastic body is utilized by setting the height of the elastic body so that a load is created in a level between a surface pressure of allowing a sealing and a surface pressure of destroying the elastic body and, moreover, there may be provided a stroke space which absorbs a tolerance of a straight member or elastic body to be sealed with a distortion amount of the elastic body and the distortion ratio and height of the elastic body may be set so as to obtain a load for generating a surface pressure for allowing a sealing to be applied to a member having an error within the tolerance.

Here, a fluorine-based rubber is, for example, used as a material for the elastic body provided on the parting surface of the molding die, thereby obtaining an elastic body resin-tight structure having an excellent heat resistance, elasticity and non-adhesiveness to the mold resin.

By this configuration as described above, the amount of distortion can be set to be a great value by making the elastic body to have a large height with respect to the sealing surface level, which can be realized using a amount of flexure that can absorb tolerances in the thickness of the straight member or in the assembly as well as tolerances in the molding die.

In addition, in the case where a plurality of portions in one straight member are exposed from the package, elastic bodies independently are distorted so that the respective elastic bodies generate surface pressures to enable sealing and can function as sealing members even when there is dispersion in the dimensions of the respective portions. In addition, it becomes possible to increase the tolerance of the straight member by adopting a resin-tight structure made of elastic bodies, so that a reduction in the cost of the straight member and a shortening of the manufacturing process can be achieved.

Furthermore, since the heat sink is pressed against the bottom surface of the cavity by means of the pressing pins, the melt resin can be prevented from extruding into the exposed portions on the rear surface of the heat sink, thereby the process of removing burrs from the rear surface of the package is unnecessary so that an increase in production efficiency can be achieved.

Since the contact portion of the bottom surface of the cavity with the heat sink is made to have a smooth surface, generation of unevenness on the exposed portion of the heat sink (lower surface of the heat sink) due to a resin pressure can be prevented. Accordingly, when an insulating layer is provided on the exposed portions of the heat sink, generation of an air layer can be prevented so that the number of defective products is reduced and an increase in production efficiency can be achieved.

In the configuration where a straight member having a hole, such as a nut, is integrally formed with other members by means of transfer molding, since the elastic sealing members (5a and 5c) are used on both sides, upper and lower sides, of the nut and, therefore, the melted resin can be blocked from flowing into the nut hole and it is not necessary to use a cap nut having one side of the hole blocked, so that a reduction in the cost of the straight member can be achieved.

In addition, in the case where a part having a protrusion (4), such as a terminal unit, is integrally formed by means of transfer molding, an escape hole (6) is created in the elastic body so as to receive the protruding portion and a frame is inserted and provided on the inner wall of the hole and, therefore, the elastic body can be prevented from being deformed due to a resin pressure while maintaining its rigidity.

Second Embodiment

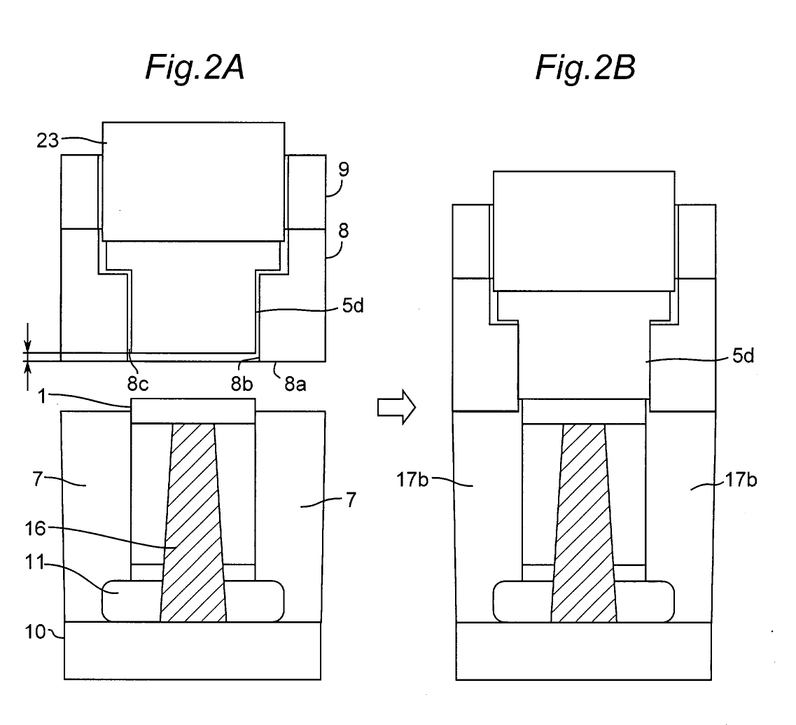

FIGS. 2A and 2B are cross sectional views schematically showing a molding structure for formation of a semiconductor device according to a second embodiment of the present invention. Descriptions of parts in the basic configuration of the present embodiment analogous to parts in the first embodiment, shown in FIGS. 1A to 1E, are omitted for brevity. The configuration of the second embodiment differs from that of the first embodiment in the point that a resin-tight structure is implemented by means of pressure in the second embodiment between the outer periphery surface of the sidewall of the elastic body, provided within the upper mold cavity insert 8, and the inner periphery surfaces of the sidewall of an elastic body insertion hole of the cavity insert block 8.

In these figures, an elastic body provided within an upper mold cavity insert block 8 is denoted by reference numeral 5d. The bottom surface of the elastic body 5d is set at a height so as not to protrude from an upper mold parting surface 8a in a position slightly recessed in the inward direction in the upper mold parting surface and the diameter of a hole 8b, into which the elastic body 5d is inserted, is set at a size having a clearance 8c when the elastic body 5d is inserted. An upper surface side (in the figure) of the elastic body 5d opposite to the side that presses the exposed surface of the lead frame 1 is securely supported by a pressing block 23. This pressing block 23 penetrates through a die chase block and is secured by a packing plate (not shown).

In the following, the operation of the second embodiment is described. First, an exposed lead frame 1 and a heat sink 11 connected to the lead frame are inserted into a lower mold cavity 7, which is clamped by an upper molding die at the time of molding formation. At this time, the elastic body 5d is pressed against the upper surface of the lead frame 1, and thereby expands in the diameter direction of the insertion hole 8b (lateral direction in FIG. 2A) due to the elasticity of the elastic body itself. Thus, the clearance 8c is filled up and blocked with the expansion of the elastic body which presses the inner periphery surface of the sidewall of the insertion hole 8b.

After carrying out the mold-clamping process, as shown in FIG. 2B, the melted epoxy resin 17b is subject to an injection pressure by means of a plunger 14 (as shown in FIG. 1A) and is injected into the lower mold cavity 7. At this time, the elastic body 5d generates a surface pressure against the inner side surface of the elastic body insertion hole 8b of the upper mold cavity insert block 8 so that the sealing effect is exercised against the resin pressure of the melted epoxy resin 17b and, thus, the resin-tight structure is realized to prevent the resin from entering the clearance 8c.

In the above described structure, when the elastic body is distorted in the longitudinal direction by the mold-clamping, the elastic body expands in the lateral direction, and this distortion due expansion in the lateral direction is utilized to generate a surface pressure required for the resin-tight function against the inner periphery surface of the elastic body insertion hole 8b of the molding die. In order to obtain the distortion amount as desired above, the diameter dimensions of the insertion hole as well as the external diameter and height dimensions of the elastic body are suitably determined.

As described above, according to the structure of the second embodiment, the elastic body 5d is set at a height so that the bottom surface thereof does not protrude from the upper die parting surface 8a, while the diameter of the elastic body insertion hole 8b is set to a suitable size having a clearance when the elastic body 8d is inserted. Therefore, the elastic body does not make contact with the edge portion of the upper mold cavity insert 8 and, thus, scratches to the elastic body are prevented. Accordingly, the lifetime of the elastic body is prolonged and the resin can be prevented from entering into such scratches, thereby preventing breakdown or deformation of the elastic body.

In addition, when the elastic body is distorted in the longitudinal direction by mold-clamping, the elastic body expands in the lateral direction and this expanded distortion in the lateral direction is utilized to generate a surface pressure required for the resin-tight function on the inner periphery surface of the elastic body insertion hole in the molding die and the diameter dimensions of the insertion hole and the external diameter and height dimensions of the elastic body are so set as to obtain the desired distortion amount. Thus, the structure can prevent the invasion of the resin from a gap between the elastic body and the molding die without fail. In addition, the elastic body has a resin sealing function as well as a resin-tight function and, therefore, the resin sealing structure becomes simple.

In the above described structure, it may be constructed such that the elastic bodies can be replaced by removing a die packing plate alone. Thus, members around the molding die cavity need not be disassembled when the elastic bodies are replaced, and therefore the replacement task is simplified and the production process need not be temporarily stopped for replacement of the elastic bodies and productivity can be increased.

Third Embodiment

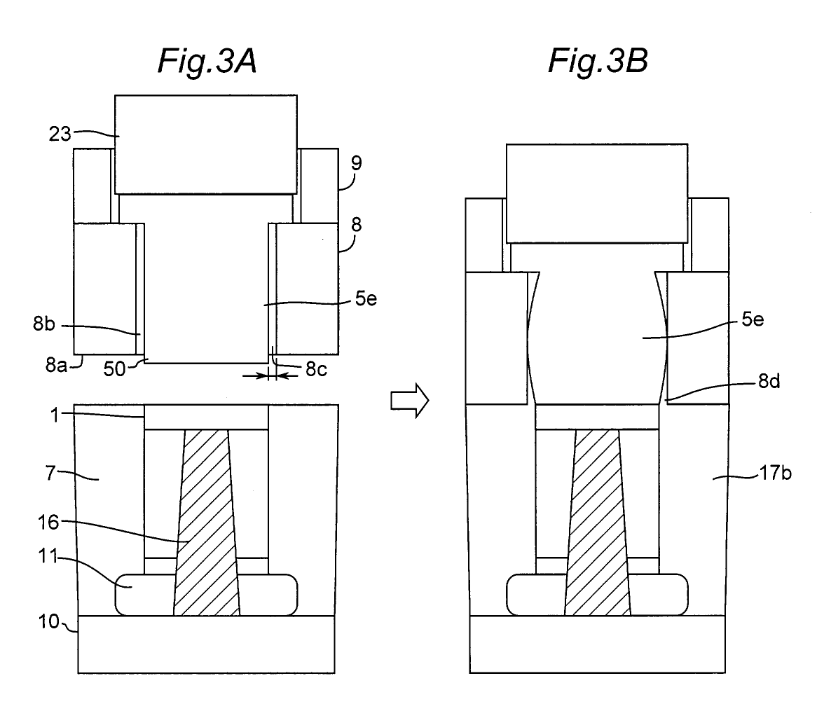

FIGS. 3A and 3B is a cross sectional view schematically showing a molding structure for formation of a semiconductor device according to a third embodiment of the present invention. The present embodiment is a modification of the second embodiment shown in FIGS. 2A and 2B, and the configuration differs from that of the second embodiment in the point that the lower edge surface of the elastic body provided within the upper mold cavity insert block 8 is designed to be in a position slightly protruding (50) from the upper die parting surface in the third embodiment so that the degree of freedom of the clearance when the elastic body is inserted is designed to be greater than that of the second embodiment.

In FIGS. 3A and 3B, an elastic body 5e is provided within an upper mold cavity insert block 8. In a stage before executing a mold-clamping process, the elastic body 5e is designed to have a height of the bottom surface thereof slightly protruding in a downward direction to the outside from the upper die parting surface 8a in the upper molding die. In this construction, the diameter of hole 8b for receiving the elastic body 5e is set so that the size of the clearance 8c, which is formed when the elastic body 5e is inserted, has a freedom greater than that in the case of the second embodiment.

In the following, the operation of the third embodiment is described. First, an exposed lead frame 1 and a heat sink 11 connected to the lead frame are inserted into a lower mold cavity 7, which is clamped by an upper molding die at the time of molding formation. At this time, the elastic body 5e is pressed against the upper surface of the lead frame 1, and thereby expands in the diameter direction of the insertion hole 8b (i.e., in a lateral direction as shown in FIG. 3B) due to the elasticity of the elastic body itself. Thus, the clearance 8c is filled up and blocked with the expansion of the elastic body which presses the inner periphery surface of the sidewall of the insertion hole 8b, at an intermediate height of the elastic body 5e.

In the above described structure, when the elastic body is distorted in the longitudinal direction by the mold-clamping, the elastic body expands in the lateral direction, and this distortion due expansion in the lateral direction is utilized to generate a surface pressure required for the resin-tight function against the inner periphery surface of the elastic body insertion hole 8b of the molding die. In order to obtain the distortion amount as desired above, the diameter dimensions of the insertion hole as well as the external diameter and height dimensions of the elastic body are suitably determined, in the same manner as in the case of the second embodiment.

In particular, in the third embodiment, the elastic body 5e is so designed as to have a height level of the bottom surface thereof to be positioned at the same surface level as the upper die parting surface 8a or at an upper surface level which does not protrude from the upper die parting surface 8a, due to the distortion in the longitudinal direction of the elastic body 5e in the mold-clamping process as shown in FIG. 3B.

At this time, the diameters of the insertion hole 8b and of the elastic body 5e are set so that a gap 8d is created between the opening peripheral edge of the insertion hole 8b and the lower peripheral edge of the elastic body when the bottom surface of the protruding portion 50 of the elastic body 5e is abutted by pressure to the exposed parting surface of the upper surface (1a) of the lead frame 1, where the exposed parting surface (1a) is formed as a resin-tight region.

After carrying out the mold-clamping process, as shown in FIG. 3B, the melted epoxy resin 17b is subject to an injection pressure by means of a plunger 14 (as shown in FIG. 1A) and is injected into the lower mold cavity 7. At this time, the elastic body 5d generates a surface pressure against the inner side surface of the elastic body insertion hole 8b of the upper mold cavity insert block 8 so that the sealing effect is exercised against the resin pressure of the melted epoxy resin 17b and, thus, the resin-tight structure is realized to prevent the resin from entering through the clearance.

As described above, according to the structure of the third embodiment, the elastic body 5d is set at the same level in height as that of the upper die parting surface 8a or a height so that the bottom surface thereof does not protrude from the upper die parting surface 8a, while the diameter of the elastic body insertion hole 8b is set to a suitable size having a clearance with a great freedom when the elastic body 8e is inserted.

Therefore, the elastic body does not make contact with the edge portion of the upper mold cavity insert block 8 and, thus, scratches to the elastic body are prevented. Accordingly, the lifetime of the elastic body is prolonged and the resin can be prevented from entering into such scratches, thereby preventing breakdown or deformation of the elastic body.

In addition, when the elastic body is distorted in the longitudinal direction by mold-clamping, the elastic body expands in the lateral direction and this expanded distortion in the lateral direction is utilized to generate a surface pressure required for the resin-tight function on the inner periphery surface of the elastic body insertion hole in the molding die, and the diameter dimensions of the insertion hole and the external diameter and height dimensions of the elastic body are so set as to obtain the desired distortion amount.

Thus, the structure can prevent the invasion of the resin from a gap between the elastic body and the molding die without fail. In addition, the elastic body has a resin sealing function as well as a resin-tight function and, therefore, the resin sealing structure becomes simple.

In addition, the stroke space for movement of the elastic body can be set in accordance with the dimensions to be absorbed, such as tolerances in dimensions of the straight member, and the surface pressure required for resin-tight sealing can be obtained even when the exposed upper surface of such as the lead frame does not protrude from the die parting surface, and therefore the amount of distortion of the elastic body can be secured according to the tolerance amount in dimension to be absorbed.

In addition, the diameters of the upper die parting surface 8a and of the elastic body 5e are designed so that a gap 8d is created between the opening peripheral edge of insertion hole 8b and the lower peripheral edge of the elastic body when the bottom surface of the protruding portion 50 of the elastic body 5e is abutted by pressure contact with the exposed parting surface of the lead frame at the time of the mold-clamping process.

Therefore, it becomes unnecessary to make the insertion hole 8b deep in the where it is necessary to make a compression distance of the elastic body large when dispersion is great in the dimension of the thickness. Thus, not only miniaturization of the device and cost reduction can be achieved but, also, damages due to contact of the opening edge of the insertion hole 8b with the lower edge of the elastic body can be prevented.

Fourth Embodiment

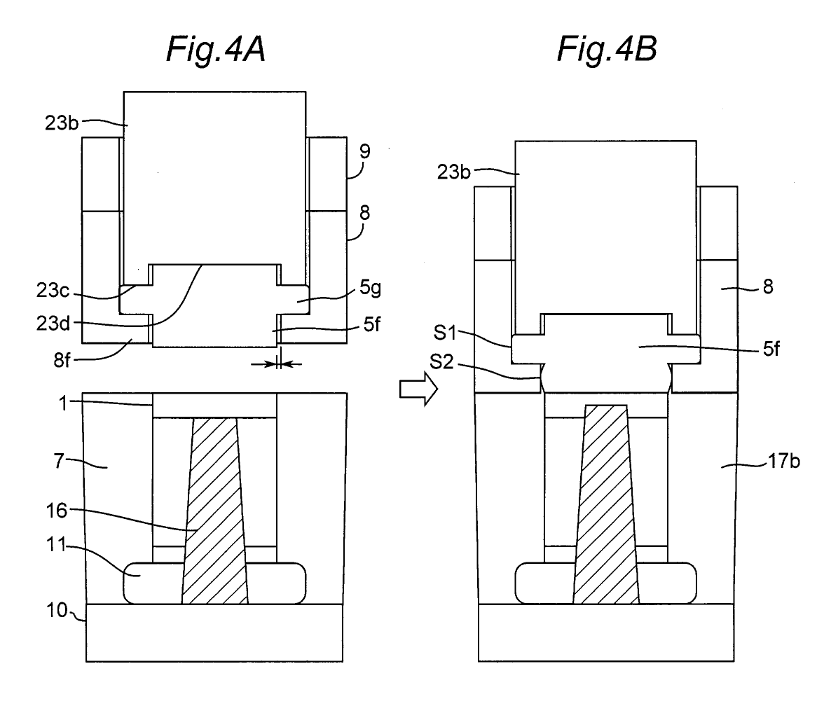

FIGS. 4A and 4B is a cross sectional view schematically showing a molding structure for formation of a semiconductor device according to a fourth embodiment of the present invention. The present embodiment is another modification of the second embodiment shown in FIGS. 2A and 2B and the basic configuration thereof is the same as that of the third embodiment shown in FIGS. 3A and 3B.

The fourth embodiment is structurally different from the third embodiment in the point that a flange portion 5g is formed around an side surface of an elastic body 5f which is provided within the upper mold cavity insert block 8, and the flange portion 5g is held between a pressing block 23b and a bottom portion 8f of the upper mold cavity insert block 8.

As shown in FIG. 4A, the bottom surface of the pressing block 23b, which presses against the upper surface of the elastic body 5f and flange portion 5g, has a two-stage configuration. In specific, the first bottom surface 23c presses against the upper surface of the flange portion 5g and the second bottom surface 23d presses against the upper surface of the main elastic body 5f, respectively.

In particular, the first bottom surface 23c forms the first resin-tight sealing function portion S1 as a pre-pressuring function that generates a surface pressure necessary for the sealing function on the inner periphery surface of the elastic body insertion hole in the cavity insert block 8 when the elastic body 5f is provided within the upper mold cavity insert block 8. The second bottom surface 23d creates a resilient force when the exposed upper surface of the lead frame 1 is pressed by the elastic body, and forms the second resin-tight sealing function portion S2 for pressing against the inner periphery surface of the sidewall of the elastic body insertion hole of the bottom portion 8f of the upper mold cavity insert block 8 due to the expansion of the bottom portion of the elastic body 5f in the lateral direction.

By forming the second resin-tight sealing function portion S2 as described above, when the elastic body 5f is pressed against the lead frame 1, the elastic body itself expands in the lateral direction due to its elasticity so that the elastic body 5f presses against the inner periphery surface of the sidewall of the elastic body insertion hole in the bottom portion 8f of the upper mold cavity insert block 8, thereby generating a surface pressure required for resin-tight sealing against a resin pressure of the melted epoxy resin 17b so as to prevent invasion of the resin.

In this configuration, the diameter of the elastic body insertion hole 8b is so designed in size as to form a clearance when the elastic body 5f is inserted therein, so that the elastic body does not make contact with the edge portion of the upper mold cavity insert block 8, which prevents the elastic body from being scratched in the same manner as in the cases of the second and third embodiments.

According to the present embodiment, the bottom surface of the pressing block 23b has a two-stage configuration where the first bottom surface 23c presses against the upper surface of the flange portion 5g and the second bottom surface 23d presses against the upper surface of the main elastic body 5f, respectively. Thus, the first resin-tight sealing function portion S1 is formed to have a pre-pressuring function and the second resin-tight sealing function portion S2 is formed to press against the inner periphery surfaces of the sidewall of the bottom portion 8f of the upper mold cavity insert block 8 by utilizing the expansion of the bottom portion of elastic body 5f in the lateral direction.

By this configuration, the first resin-tight sealing function portion S1 can surely prevent the resin from flowing into the inside of the molding die even when a mis-aligned shot is generated due to an insufficient amount of distortion, in comparison with the normal amount of distortion, of the elastic body caused by incorrect setting of the frame, or the like, in the molding die structure having a gap between the elastic body and the molding die.

In addition, even in the case where the amount of distortion of the elastic body is small and the expansion in the lateral direction caused by the pressure is insufficient, the first resin-tight sealing function portion S1 can effectively act to prevent the resin from flowing into the inside of the molding die.

Fifth Embodiment

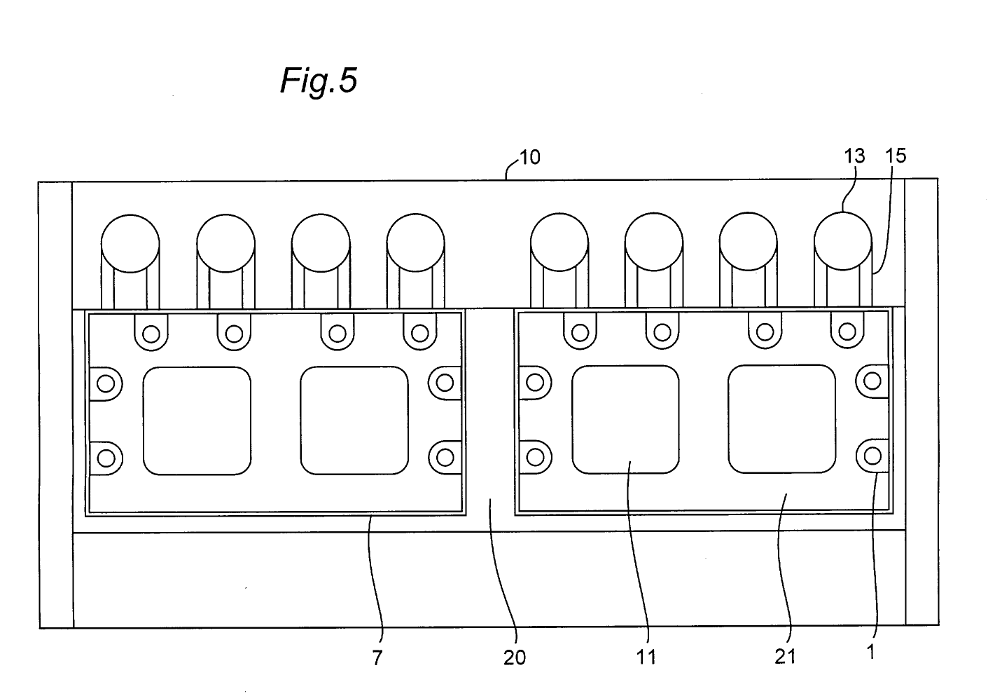

FIG. 5 shows a resin sealing structure for a power module according to a fifth embodiment of the present invention, and in particular shows a layout diagram of a lower molding die of a resin sealing device containing a product for a semiconductor device where the resin sealing device is provided with a multiple chambers in one mold cavity.

As shown in FIG. 5, the same amounts of epoxy resin tablets (not shown) are respectively introduced, at the time of transfer molding, into a plurality of chamber 13 laid out as shown in the figure, and after a mold-clamping process is carried out using the upper molding die, injection molding of the resin is carried out.

After the completion of the mold-clamping process, the melted epoxy resin introduced into a plurality of chambers 13 is injected into the lower mold cavity 7 formed in the cavity insert block 20 through the gate 15 from the cull 12 which is formed in the upper mold retainer 9, by means of the plunger 14 for injection as shown in FIG. 1 and, then, pressure is applied to the resin. The injected melted epoxy resin 17b flows through within the lower mold cavity 7 so that the product is sealed with the resin.

The epoxy resin 17b, which is thermoset, is cured during the mold-clamping process and, after opening the molding die, the hardened epoxy resin is taken out of the lower mold cavity 7 using an ejector (not shown), or the like, and this becomes a semiconductor device 21 sealed with the resin.

According to the above described configuration, the injection pressure of the resin can be lowered and, therefore, not only generation of resin burrs can be reduced, but also modification of the gate form in accordance with the cavity and injection control such as an injection speed can be executed.

In addition, the resin can be uniformly supplied to a package having a large volume to be molded such as a module, so that the injection conditions of the resin become stable and production efficiency is increased. In addition, the lengths of runners from the respective chambers to the package can be made uniform and, therefore, dispersion in quantity of heat received by the injected resin is small and the conditions for the molding formation process become stable so that production efficiency is increased.

As described above according to the present invention, a manufacturing method for a semiconductor device, a resin sealing device and a resin molding method can be provided where a resin-tight sealing function for the exposed surfaces of a member to be exposed at the time of molding can be achieved at a low surface pressure, and the press load is reduced to increase utilization efficiency of a power and production efficiency.

In addition according to the present invention, a resin-tight structure of an elastic body is adopted and the elastic body is provided with formation of a gap so as to prevent the elastic body from making contact with the insert edge of the molding die, and therefore the resin is prevented from invading this gap and from generating burrs that cause defects in the product.

In addition, an amount of flexure of an elastic body is set as to absorb the tolerances of the thickness of the straight member and of the assembly as well as the tolerance of the molding die, and it becomes possible to increase the tolerance of the straight member even in the case where there is dispersion in the dimensions of the portions, in one straight member, exposed at a plurality of locations in the package, thereby reduction in cost of the straight member and shortening of the manufacturing process can be achieved.

Furthermore, the melted resin can be prevented from extruding to the exposed portions of the rear surface of the heat sink and the process of removal of burrs from the rear surface of the package becomes unnecessary, so that a resin sealing structure and a resin molding method for a semiconductor device can be provided with a high production efficiency.

In addition, unevenness due to the pressure from the resin does not occur in the exposed portion of the heat sink, so that generation of an air layer can be prevented when an insulating layer is provided over the exposed portion of the heat sink in the product, whereby the number of defective products is reduced and production efficiency is increased.

Furthermore, in the configuration where a straight member having a hole, such as a nut, is integrally formed with other members by transfer molding, the resin can be blocked from flowing into the nut hole and a reduction in cost of the straight member can be achieved.

In addition, in the case where a part having a protrusion, such as a terminal part, is integrally formed by transfer molding, the rigidity of the elastic body can be maintained and, at the same time, the elastic body can be prevented from being deformed due to pressure from the resin.

Furthermore, in the configuration with the elastic body to form a gap that prevents the elastic body from making contact with the insert edge of the molding die, a resin sealing structure for a semiconductor device and a resin molding method can be provided where the lifetime of the elastic body is prolonged, preventing the resin from entering such a scratch due to contact, preventing deformation or destroy of the elastic body, and preventing the resin from entering through gap between the elastic body and the molding die with a simple sealing structure.

In addition, not only the generation of resin burrs can be reduced, but also modification of the gate forms according to the cavity and injection control such as injection speed can be executed and the resin can be uniformly supplied to a package of a large volume to be molded such as a module, and the resin injection conditions are stable and production efficiency is increased.

Although the present invention has been described in connection with the preferred embodiments thereof with reference to the accompanying drawings, it is to be noted that various changes and modifications will be apparent to those skilled in the art. Such changes and modifications are to be understood as included within the scope of the present invention as defined by the appended claims, unless they depart therefrom.

What is claimed is:

1. A method for manufacturing a semiconductor device through molding with a seal resin, comprising:
mold-clamping upper and lower mold blocks to be fitted each other by confronting upper and lower mold cavities of said upper and lower mold blocks, respectively;
injecting the seal resin into said upper and lower mold cavities under the mold-clamped condition; and
integrally sealing a lead frame, a semiconductor chip held by the lead frame and a nut disposed on a terminal portion of the lead frame to be covered with the injected seal resin under the mold-clamped condition,
wherein upper and lower sides of the nut are pressed by upper and lower elastic members, respectively, under the mold-clamped condition, to thereby provide a resin-tight structure for preventing contact with the seal resin.

2. The method according to claim 1, wherein the lower elastic member is secured at a top end of a support post protruding from a bottom inner surface of the lower mold cavity, the nut is mounted on the upper side of the lower elastic member, the terminal portion of the lead frame is disposed on an upper side of the nut, the upper elastic member provided in the upper mold cavity is abutted to the terminal portion of the lead frame by pressure, so that the nut and the lead frame are integrally fixed by curing the seal resin.

3. A method for manufacturing a semiconductor device through molding with a seal resin, comprising:
mold-clamping upper and lower mold blocks to be fitted each other by confronting upper and lower mold cavities of said upper and lower mold blocks, respectively;
injecting the seal resin into said upper and lower mold cavities under the mold-clamped condition; and
integrally sealing a lead frame, a semiconductor chip held by the lead frame and a radiator plate having a quadrangular main surface on which the lead frame is fixed, to be covered with the injected seal resin under the mold-clamped condition, while a rear surface of the radiator plate is exposed from the seal resin,
wherein a pin provided in the upper mold block is abutted to at least a portion of the main surface of the radiator plate in the vicinity of the side region integrally fixed to the lead frame portion, and wherein the rear surface of the radiator plate is abutted by pressure onto the bottom surface of the lower mold cavity, under the mold-clamped condition.

4. The method according to claim 3, wherein the tip of the pin is abutted by pressure contact with the main surface of the radiator plate by forcing the pin using a pin forcing spring.

5. A method for manufacturing a semiconductor device through molding with a seal resin, comprising:
mold-clamping upper and lower mold blocks to be fitted each other by confronting upper and lower mold cavities of said upper and lower mold blocks, respectively;
injecting the seal resin into said upper and lower mold cavities under the mold-clamped condition; and
integrally sealing a lead frame and a semiconductor chip held by the lead frame, to be covered with the injected seal resin under the mold-clamped condition,
wherein, when in the mold-clamping, a stick-shaped electrode protruding upward from the semiconductor chip is entirely received by a cylinder body protruding downward from the upper mold block and an elastic member provided at least around a tip end of the cylinder body is contacted with a surface of the semiconductor chip.

6. The method according to claim 5, wherein the cylinder body is formed of a double cylinder structure including an elastic cylinder body and a rigid cylinder body inserted into the elastic cylinder body.

7. A resin sealing device for a semiconductor device, comprising:
a pair of upper and lower mold blocks to be mold-clamped each other, forming upper and lower mold cavities of said upper and lower mold blocks, respectively, to be confronted;
said upper and lower mold cavities to be filled with a seal resin under the mold-clamped condition; and
a lead frame and a semiconductor chip held by the lead frame, to be integrally sealed with the seal resin under the mold-clamped condition,
wherein a through-hole is formed in, at least, one of the upper mold block and the lower mold block, and an elastic member is provided within the through-hole,
wherein, the elastic member is deformed under the mold-clamped condition so that a tip end of the elastic member is tightly contacted with a non-seal surface region of the lead frame to thereby prevent the seal resin from entering the non-seal surface region of the lead frame, and that a side surface of the elastic member is contacted with an inner side surface of the through-hole to thereby prevent the seal resin from leaking through the through-hole.

8. The resin molding device according to claim 7, having a structure such that the elastic member does not protrude from the through-hole.

9. The resin molding device according to claim 7, wherein the tip end of the elastic member sticks out from the through-hole so that a gap is created between an peripheral edge of an opening of the through-hole and the elastic member when the tip of the elastic member is contacted with the non-seal region.

10. The resin molding device according to claim 7, wherein a flange of the elastic member is held between a pressing block and a mold cavity block.

11. The resin molding device according to claim 7, wherein a multi-chamber structure is provided in one cavity.
